(19) United States
(12) Patent Application Publication
(10) Pub. No.: US 2019/0267988 A1
(43) Pub. Date: Aug. 29, 2019

(54) SWITCH-TUBE DRIVER CIRCUIT

(71) Applicant: Sengled Co., Ltd., Shanghai (CN)

(72) Inventors: Zhibin TIAN, Shanghai (CN); Jinxiang SHEN, Shanghai (CN)

(21) Appl. No.: 16/331,860

(22) PCT Filed: Sep. 19, 2017
(86) PCT No.: PCT/CN2017/102277

§ 371 Date: Mar. 8, 2019

(30) Foreign Application Priority Data
Sep. 26, 2016 (CN) 201610852800.5

(51) Int. Cl. H03K 17/284

(52) U.S. Cl. CPC H03K 17/284

(57) ABSTRACT

A switch-tube driver circuit is provided, comprising: a first field effect tube, a control element, a first time delay circuit, and a second time delay circuit. The first time delay circuit comprises: a first resistor and a first capacitor. The second time delay circuit comprises: a second resistor and a second capacitor. A gate electrode of the first field effect tube is connected to the signal input interface, a source electrode of the first field effect tube is connected to ground, and a drain electrode of the first field tube is connected to an end of the first transistor, an end of the first capacitor, and a first end of the control element, respectively. The other end of the first resistor accesses a bias voltage and is connected to an end of the second resistor, and the other end of the first capacitor is connected to ground.

### CROSS-REFERENCES TO RELATED APPLICATIONS

This application is a national phase entry under 35 U.S.C. § 371 of International Application No. PCT/CN2017/102277, filed on Sep. 19, 2017, which claims the priority of Chinese Patent Application No. 201610852800.5 filed on Sep. 26, 2016, the entire contents of both of which are incorporated herein by reference.

### FIELD OF THE DISCLOSURE

The present disclosure generally relates to the technology of driver circuit and, more particularly, relates to a switch-tube driver circuit.

### BACKGROUND

As the control voltage of the integrated circuit continues to increase, in industry, to ensure safety of the circuit, a switch tube is used as the switch in the integrated circuit, and the switch tube is controlled through a driving signal. In certain application scenarios, to control the timing sequence of the integrated circuit and to protect the safety of the integrated circuit, the switch tube needs to have different driving speeds, and the switch-tube is only controlled after the driving signal of the switch-tube is delayed.

Often, the regulation circuit for delaying the driving of the switch-tube is implemented by introduction of additional resistor(s) and diode(s), where the diode is configured to define the direction of the driving signal. One end of the resistor accesses the driving signal, and the other end of the resistor is connected to the switch tube, such that the driving signal is delayed by traversing the resistor before turning on the switch tube.

However, using the existing technologies, the delay time of the driving signal cannot be controlled properly.

### BRIEF SUMMARY OF THE DISCLOSURE

One aspect of the present disclosure discloses a switch-tube driver circuit in order to realize the precise control of the delay time of the driving signal.

According to the present disclosure, the switch-tube driver circuit comprises: a first field effect tube, a control element, a first time delay circuit, and a second time delay circuit. The first time delay circuit comprises: a first resistor and a first capacitor, and the second time delay circuit comprises: a second resistor and a second capacitor.

A gate electrode of the first field effect tube is connected to the signal input interface, a source electrode of the first field effect tube is connected to ground, and a drain electrode of the first field tube is connected to an end of the first transistor, an end of the first capacitor, and a first end of the control element, respectively. The other end of the first resistor accesses a bias voltage and is connected to an end of the second resistor, and the other end of the first capacitor is connected to ground. Further, the other end of the second resistor is connected to a second end of the control element, an end of the second capacitor, and a switch-tube, respectively. The other end of the second capacitor is connected to ground, and a third end of the control element is connected to ground.

In one embodiment of the present disclosure, the control element is a second field effect tube. The first end of the control element is a gate electrode of the second field effect tube, the second end of the control element is a drain electrode of the second field effect tube, and the third end of the control element is a source electrode of the second field effect tube.

In one embodiment of the present disclosure, the control element is a Zener diode. The first end of the control element is a reference end of the Zener diode, the second end of the control element is a cathode end of the Zener diode, and the third end of the control element is an anode end of the Zener diode.

In one embodiment, the first field effect tube and the second field effect tube may be enhancement-mode N-MOS (N-channel metal-oxide semiconductor) field effect tubes.

Optionally, in the aforementioned embodiments, the switch tube is an enhancement-mode N-MOS field effect tube.

Another aspect of the present disclosure discloses another switch-tube driver circuit. The switch-tube driver circuit includes a first field effect tube, a control element, a first time delay circuit, a second time delay circuit, and a switch-tube. The first time delay circuit includes a first resistor and a first capacitor. The second time delay circuit comprises a second resistor and a second capacitor. The switch-tube is tuned on at a delayed time after the first field effect tube is turned on.

Further, the delayed time corresponds to values of the first resistor, the first capacitor, the second resistor, and the second capacitor.

Another aspect of the present disclosure discloses another switch-tube driver circuit. The driver includes a first field effect tube, a control element, a first time delay circuit, a second time delay circuit, and a switch-tube. The first time delay circuit comprises a first resistor and a first capacitor; the second time delay circuit comprises a second resistor and a second capacitor; and the switch-tube is tuned off at a delayed time after the first field effect tube is turned off.

Further, the delayed time corresponds to values of the first resistor, the first capacitor, the second resistor, and the second capacitor.

As such, the present disclosure provides a switch-tube driver circuit, comprising: a first field effect tube, a control element, a first time delay circuit, and a second time delay circuit, where the first time delay circuit comprises: a first resistor and a first capacitor, and the second time delay circuit comprises: a second resistor and a second capacitor. A gate electrode of the first field effect tube is connected to the signal input interface, a source electrode of the first field effect tube is connected to ground, and a drain electrode of the first field tube is connected to an end of the first transistor, an end of the first capacitor, and a first end of the control element, respectively. The other end of the first resistor accesses a bias voltage and is connected to an end of the second resistor, and the other end of the first capacitor is connected to ground. The other end of the second resistor is connected to a second end of the control element, an end of the second capacitor, and a switch-tube, respectively. Further, the other end of the second capacitor is connected to ground, and a third end of the control element is connected to ground. By using the switch-tube driver circuit provided by embodiments of the present disclosure, the delay time of the driving signal may be precisely controlled.

### BRIEF DESCRIPTION OF THE DRAWINGS

To more clearly illustrate the technical solutions in embodiments of the present invention or the prior art, the accompanying drawings needed for describing the disclosed embodiments or the prior art are briefly introduced hereinafter. Obviously, the accompanying drawings in the following descriptions are merely some embodiments of the present invention. Based on such accompanying drawings, other drawings may be obtainable by those ordinarily skilled in the art without creative effort.

FIG. 1 illustrates a structural schematic view of a switch-tube driver circuit consistent with embodiments of the present disclosure;

FIG. 2 is a schematic diagram illustrating switching delay in a switch-tube driver circuit consistent with embodiments of the present disclosure;

FIG. 3 illustrates a structural schematic view of another switch-tube driver circuit consistent with embodiments of the present disclosure; and

FIG. 4 illustrates a structural schematic view of another switch-tube driver circuit consistent with embodiments of the present disclosure.

### DETAILED DESCRIPTION

With reference to the accompanying drawings in embodiments of the present disclosure, technical solutions of the present disclosure are described more fully hereinafter. Obviously, the described embodiments are only some embodiments of the present disclosure, but not all embodiments. Based on the disclosed embodiments, all other embodiments obtainable by those ordinarily skilled in the relevant art without creative labor shall fall within the protection scope of the present disclosure.

Terms such as “first”, “second”, “third”, and “fourth”, etc. (if exists) in the specification, claims, and the aforementioned accompanying drawings are used to differentiate similar objects, and may not necessarily used to illustrate specific order or sequence. It should be understood that data used in such way may be exchanged under proper situations, thus allowing the disclosed embodiments described herein to be implemented in other orders than that illustrated or described here. Further, terms of “comprising” and “including” and any their derivatives are intended to cover non-excluding inclusions. For example, a process, method, system, product or device comprising a series of steps or units are not necessarily limited to those clearly listed steps or units, but may include steps or units not clearly listed, or other steps or units intrinsic to such process, method, product or device.

With reference to specific embodiments, technical solutions of the present disclosure are illustrated in detail hereinafter. The specific embodiments below may be combined with each other, and the same or similar concepts or processes are not repeatedly described in certain embodiments.

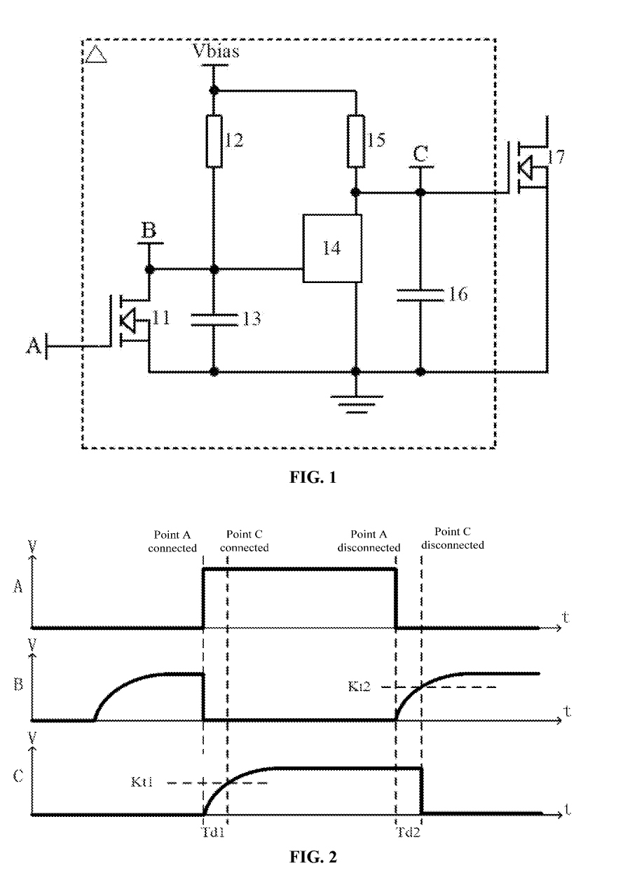

FIG. 1 illustrates a structural schematic view of a switch-tube driver circuit consistent with embodiments of the present disclosure. As shown in FIG. 1, the switch-tube driver circuit comprises: a first field effect tube 11, a control element 14, a first time delay circuit, and a second time delay circuit. The first time delay circuit comprises a first resistor 12 and a first capacitor 13. The second time delay circuit comprises a second resistor 15 and a second capacitor 16.

More specifically, a gate electrode of the first field effect tube 11 is connected to a signal input interface, a source electrode of the first field effect tube 11 is connected to ground, and a drain electrode of the first field effect tube 11 is connected to an end of the first resistor 12, an end of the first capacitor 13, and a first end of the control element 14, respectively. The other end of the first resistor 12 accesses a bias voltage and is connected to an end of the second resistor 15; and the other end of the first capacitor 13 is connected to ground. The other end of the second resistor 15 is connected to a second end of the control element 14, an end of the second capacitor 16, and a switch tube 17. Further, the other end of the second capacitor 16 is connected to ground, and a third end of the control element 14 is connected to ground.

Further, referring to FIG. 1, point A may receive a driving signal inputted into the switch-tube driver circuit, and point C may output the driving signal after traversing the switch-tube driver circuit.

When the driving signal is inputted into the switch-tube driver circuit via point A, the voltage level at point A may change from a low voltage level to a high voltage level, and the first field effect tube 11 is turned on. Under the effect of the first effect tube 11, the voltage level at point B changes from a high voltage level to a low voltage level, thus forcing the control element 14 to disconnect its second end from the third end. Further, the bias voltage Vbias charges the second capacitor 16 via the second resistor 15, and when the voltage level at point C is raised to a turn-on threshold of the switch tube 17, the switch tube 17 is turned on. As such, after being delayed by traversing the switch-tube driver circuit, the driving signal may turn on the switch tube.

When point A is disconnected (i.e., no driving signal is inputted), the voltage level at point A may change from a high voltage level to a low voltage level, and the first field effect tube 11 is turned off. Thus, the bias voltage Vbias charges the first capacitor 13 through the first resistor 12, and when the voltage level at point B is raised to the turn-on voltage of the control unit 14, the control unit 14 is turned on. Further, the voltage level at point C may change from a high voltage level to a low voltage level, and the switch tube 17 is turned off

FIG. 2 is a schematic diagram illustrating switching delay in a switch-tube driver circuit consistent with embodiments of the present disclosure. As shown in FIG. 2, three diagrams are provided to illustrate variation of the voltage level with the time at points A, B, and C, respectively. When point A is in a low voltage level and receives no input of the driving signal, the bias voltage charges the first capacitor 13 via the first resistor 12, and the point C is disconnected. That is, when no driving signal is inputted at point A, no signal is outputted at point C. Further, because the bias voltage Vbias charges the first capacitor 13 through the first resistor 12, the voltage level at point B may be gradually raised to the turn-on voltage of the control unit 14.

Further, when the driving signal is inputted to the disclosed circuit via point A, the voltage level at point A may change from the low voltage level to a high voltage level, and the voltage level at point B changes into a low voltage level. Because the bias voltage Vbias charges the second capacitor 16 via the second resistor 15, the voltage level at point C may be raised to a turn-on threshold Kt1 of the switch tube 17. Accordingly, the switch tube 17 may be turned on, and the turn-on delay time Td1 is obtained to be:

$$Td 1 = - ( R 2 \cdot C 2 ) \cdot In ( 1 - \frac{Kt 1}{Vbias} ) ,$$

where R2 is the resistance of the second resistor 15, C2 is the capacitance of the second capacitor 16, and Vbias is the bias voltage.

When point A is again disconnected, namely, the driving signal is no longer being inputted, the voltage level at point A may change from the high voltage level back to the low voltage level, and the bias voltage charges the first capacitor 13 via the first resistor 12. When the voltage level at point B is raised to be equal to the turn-on threshold Kt2 of the control element 14, the voltage level at point C changes from the high voltage level to the low voltage level, and the switch tube 17 is thus turned off. The turn-off delay time Td2 is obtained from equation of

$$Td 2 = - ( R 1 \cdot C 1 ) \cdot In ( 1 - \frac{Kt 2}{Vbias} ) ,$$

where R1 is the resistance of the first resistor 12, C1 is the capacitance of the first capacitor 13, and Vbias is the bias voltage.

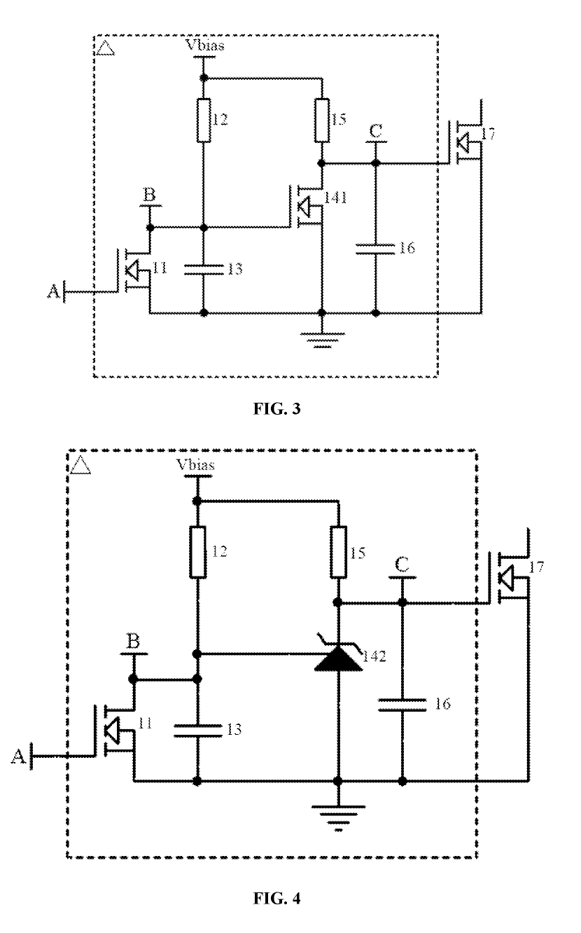

FIG. 3 illustrates a structural schematic view of another switch-tube driver circuit consistent with embodiments of the present disclosure. As shown in FIG. 3, the control element 14 may be a second field effect tube 141. In such a situation, the first end of the control element 14 may be a gate electrode of the second field effect tube 141, the second end of the control element 14 may be a drain electrode of the second field effect tube 141, and the third end of the control element 14 may be a source electrode of the second field effect tube 141.

FIG. 4 illustrates a structural schematic view of another switch-tube driver circuit consistent with embodiments of the present disclosure. As shown in FIG. 4, the control element 14 may specifically be a Zener diode 142. Correspondingly, the first end of the control element 14 may be a reference end of the Zener diode 142, the second end of the control element 14 may be a cathode end of the Zener diode 142, and the third end of the control element 14 may be an anode end of the Zener diode 142.

Optionally, in the above-described embodiments, by adjusting and applying different first field effect tube 11, first resistor 12, first capacitor 13, second resistor 15, second capacitor 16, second field effect tube 141 or Zener diode 142, and switch tube 17, the adjustment of the turn-on delay time and the turn-off delay time of the switch-tube driver circuit may be realized. For example, with reference to the above-described equation for calculating the turn-on delay time, a change in the resistance value of the second resistor 15 may lead to a change in the turn-on delay time. Accordingly, resistors with different resistance may be applied as the second resistor to yield different turn-on delay time.

Optionally, in the above-described embodiments, the first field effect tube 11 and the second field effect tube 141 may be enhancement-mode N-MOS field effect tubes.

Optionally, in the above-described embodiments, the switch tube 17 may be an enhancement-mode N-MOS field effect tube.

Optionally, in the above-described embodiments, the turn-on threshold of the switch tube 17 may be around 2 V. Further, the switch tube 17 may be a field effect tube coming in different models or sizes, thereby obtaining different turn-on thresholds.

Finally it should be illustrated that, those embodiments above are only used to illustrate technical solutions of the present disclosure, but not to limit the scope of the disclosure. Though, referring to previous embodiments, the present disclosure is illustrated in details, those ordinarily skilled in the art may still understand that the disclosed technical solutions may be modified, or either partial or entire technical characteristics may be equally exchanged. Via such modification or exchange, the nature of the corresponding technical solutions will not depart from the principles of the present disclosure.

What is claimed is:

1. A switch-tube driver circuit, comprising:
a first field effect tube;
a control element;
a first time delay circuit; and
a second time delay circuit,
wherein the first time delay circuit comprises a first resistor and a first capacitor, and the second time delay circuit comprises a second resistor and a second capacitor,
a gate electrode of the first field effect tube is connected to a signal input interface, a source electrode of the first field effect tube is connected to ground, a drain electrode of the first field effect tube is connected to an end of the first resistor, an end of the first capacitor, and a first end of the control element, respectively,
the other end of the first resistor accesses a bias voltage and is connected to an end of the second resistor, the other end of the first capacitor is connected to ground, and the other end of the second resistor is connected to a second end of the control element, an end of the second capacitor, and a switch-tube, respectively, and
the other end of the second capacitor is connected to ground, and a third end of the control element is connected to ground.

2. The circuit according to claim 1, wherein:
the control element is a second field effect tube,
the first end of the control element is a gate electrode of the second field effect tube,
the second end of the control element is a drain electrode of the second field effect tube, and
the third end of the control element is a source electrode of the second field effect tube.

3. The circuit according to claim 1, wherein:
the control element is a Zener diode,
the first end of the control element is a reference electrode of the Zener diode,
the second end of the control element is a cathode of the Zener diode, and
the third end of the control element is an anode of the Zener diode.

4. The circuit according to claim 2, wherein:
the first field effect tube and the second field effect tube are enhancement-mode N-MOS field effect tubes.

5. The circuit according to claim 1, wherein:
the switch-tube is an enhancement-mode N-MOS field effect tube.

6. A switch-tube driver circuit, comprising:
a first field effect tube;
a control element;
a first time delay circuit;
a second time delay circuit; and
a switch-tube,
wherein the first time delay circuit comprises a first resistor and a first capacitor; the second time delay circuit comprises a second resistor and a second capacitor; and the switch-tube is tuned on at a delayed time after the first field effect tube is turned on.

7. The switch-tube driver circuit of claim 6, wherein the delayed time corresponds to values of the first resistor, the first capacitor, the second resistor, and the second capacitor.

8. A switch-tube driver circuit, comprising:
a first field effect tube;
a control element;
a first time delay circuit;
a second time delay circuit; and
a switch-tube,
wherein the first time delay circuit comprises a first resistor and a first capacitor; the second time delay circuit comprises a second resistor and a second capacitor; and the switch-tube is tuned off at a delayed time after the first field effect tube is turned off

9. The switch-tube driver circuit of claim 8, wherein the delayed time corresponds to values of the first resistor, the first capacitor, the second resistor, and the second capacitor.
